(19) United States
(12) Patent Application Publication
(10) Pub. No.: US 2002/0104478 A1
(43) Pub. Date: Aug. 8, 2002

(54) Silicon carbide single crystal and process for producing the same

(76) Inventors: Emi Oguri, Nishikamo-gun (JP); Fusao Hirose, Tsukuba-city (JP); Hironari Kuno, Kariya-city (JP); Masao Nagakubo, Nishikamo-gun (JP); Shoichi Onda, Toyokawa-city (JP)

Correspondence Address: LAW OFFICE OF DAVID G POSZ, 2000 L STREET, N.W., SUITE 200, WASHINGTON, DC, 20036, US

(21) Appl. No.: 10/058,353

(22) Filed: Jan. 30, 2002

(30) Foreign Application Priority Data
Feb. 7, 2001 (JP) 2001-30477

(51) Int. Cl. C30B 28/12; C30B 25/00; C30B 28/14

(52) U.S. Cl. 117/104

(57) ABSTRACT

A silicon carbide single crystal substrate and silicon carbide raw material powder are provided in a graphite vessel. Arsenic or an arsenic compound is added to the silicon carbide raw material powder. A mixed gas obtained by mixing a gas containing arsenic with a raw material gas formed by heat sublimation of the silicon carbide raw material powder is supplied to the silicon carbide single crystal substrate to grow a silicon carbide single crystal containing arsenic. Arsenic as an n-type dopant controls the resistivity of the silicon carbide single crystal. Because it has an atomic radius equivalent to silicon, it does not compress or expand the crystal, whereby crystalline distortion is less likely to occur. As a result, formation of heterogeneous polymorphism is suppressed.

### CROSS REFERENCE TO RELATED APPLICATION

This application is based on and incorporates herein by reference Japanese Patent Application No. 2001-30477 filed on Feb. 7, 2001.

### FIELD OF THE INVENTION

The present invention relates to a silicon carbide single crystal that can be utilized, for example, as a constituent material of a semiconductor device, a light emitting diode or the like, and a process for producing the same.

### BACKGROUND OF THE INVENTION

Silicon carbide (SiC) is used as a material for a semiconductor substrate owing to its thermal and mechanical stable characteristics. A sublimation recrystallization method is one example used for growing an SiC single crystal. In this method, a heat sublimation gas of an SiC raw material powder is supplied on a seed crystal of an SiC single crystal to grow an SiC single crystal. The crystal polymorphism and the mechanical and physical properties can be controlled by controlling the growing atmosphere and the growing conditions of an SiC single crystal.

JP-A-6-1698 discloses a method, in which a silicon compound of a transition metal is added to SiC raw material powder, and the Si vapor pressure is maintained at a constant value, whereby crystallinity and uniformity are improved by preventing defects. U.S. Pat. No. 5,433,167 (JP-A-5-221796) discloses a method, in which aluminum is added to Sic raw material powder, and growing is carried out in an inert gas atmosphere containing nitrogen with controlling change of the atmospheric pressure, whereby an SiC single crystal having controlled polymorphism is obtained. U.S. Pat. Nos. 5,718,760 and 6,025,289 (International Patent Publication 2000-503968) discloses a method, in which an n-type dopant and a p-type dopant are added in order to obtain a colorless SiC single crystal.

The resistivity of the resulting SiC single crystal can be controlled by adding an impurity to an atmospheric gas. FIG. 8 shows an apparatus 10 used for growing an SiC single crystal. The apparatus 10 has a graphite vessel 1 containing Sic raw material powder 5. An SiC single crystal substrate 3 as a seed crystal is attached and fixed on a graphite pedestal 2 provided inside the graphite vessel 1. The SiC raw material powder 5 rises as a raw material gas 5a upon heating the graphite vessel 1 to a temperature higher than the sublimation temperature of SiC, and is recrystallized on the SiC single crystal substrate 3. An inlet 12, from which a gas 8b containing, for example, nitrogen, as an impurity is introduced, is provided on an upper wall of the graphite vessel 1. Nitrogen introduced from the inlet 12 is substituted on the C site of SiC to act as an n-type dopant, whereby the resistivity thereof is decreased.

A growing test is carried out according to the method shown in FIG. 8 by using a 6H-type SiC single crystal as a seed crystal. It has been found that the resulting SiC single crystal 4b has large crystalline distortion. There are some cases where 15R-type SiC is partially grown during the growing process of the SiC single crystal 4b. This is considered to arise, because the atomic radius of nitrogen substituted on the C site is smaller than that of carbon, and thus the plane distance is decreased to cause distortion in the crystal. It is thus expected that when the distortion is increased, the 15R-type crystal with a plane distance smaller than the 6H-type is grown.

When heterogeneous polymorphism is formed in this way, it becomes difficult to obtain an SiC single crystal of a large area having a desired crystal polymorphism with few defects.

### SUMMARY OF THE INVENTION

It is therefore an object of the invention to provide a process for producing an SiC single crystal, in which controllability of both resistivity and polymorphism are achieved, and formation of heterogeneous polymorphism caused by distortion in the crystal due to compression or expansion is prevented, so as to provide an SiC single crystal having high quality and low resistivity.

According to one aspect of the present invention, in a process of producing a silicon carbide single crystal by supplying a silicon carbide raw material gas on a silicon carbide single crystal substrate as a seed crystal to grow a silicon carbide single crystal, arsenic or an arsenic compound is added to a silicon carbide raw material gas.

Because arsenic, which is an n-type dopant introduced on the Si site of silicon carbide, has such an atomic radius that is equivalent to silicon, it does not cause compression or expansion of the crystal upon substitution. Thus distortion inside the crystal is less likely to occur. As a result, the formation of heterogeneous polymorphism is suppressed, whereby a silicon carbide single crystal having desired resistivity and high quality can be obtained.

According to another aspect of the present invention, in a process for producing a silicon carbide single crystal by supplying a silicon carbide raw material gas on a silicon carbide single crystal substrate as a seed crystal to grow a silicon carbide single crystal, an n-type dopant atom having a smaller atomic radius than silicon, or a compound thereof, and a metallic atom other than light metals having a larger atomic radius than silicon, or a compound thereof are added to the silicon carbide raw material gas.

The n-type dopant atom having a smaller atomic radius than silicon has a compression function of crystals. In the case where the resistivity is controlled by the n-type dopant atom, when the metallic atom other than light metals having a larger atomic radius than silicon is added, the metallic atom substituted on the Si site has an expansion function of crystals. Thus it exerts an effect of counteracting the compression function of the n-type dopant atom. Light metals are not preferred since they have large differences in atomic radius from silicon, so as to be a factor of crystal defects. Consequently, the distortion inside the crystal is relaxed, and the formation of heterogeneous polymorphism is suppressed, whereby a silicon carbide single crystal having desired resistivity and high quality can be obtained.

According to a further aspect of the present invention, in a process for producing a silicon carbide single crystal by supplying a silicon carbide raw material gas on a silicon carbide single crystal substrate as a seed crystal to grow a silicon carbide single crystal, a silicon carbide raw material gas including at least one of a p-type dopant atom having a larger atomic radius than carbon and compound thereof, and at least one of an atom having a smaller atomic radius than silicon and compound thereof is supplied. The p-type dopant atom is at least one selected from boron, aluminum and gallium. The atom having a smaller atomic radius than silicon is a carbon fluoride gas.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing an apparatus for producing a crystal according to the first embodiment of the invention;

FIG. 2 is a cross sectional view showing an apparatus for producing a crystal according to the second embodiment of the invention;

FIG. 3 is a cross sectional view showing an apparatus for producing a crystal according to the third embodiment of the invention;

FIG. 4 is a cross sectional view showing an apparatus for producing a crystal according to the fourth embodiment of the invention;

FIG. 5 is a cross sectional view showing an apparatus for producing a crystal according to the fifth embodiment of the invention;

FIG. 6 is a cross sectional view showing an apparatus for producing a crystal according to the sixth embodiment of the invention;

FIG. 7 is a cross sectional view showing an apparatus for producing a crystal according to the seventh embodiment of the invention; and

FIG. 8 is a cross sectional view showing an apparatus for producing a crystal according to a related art.

### DETAILED DESCRIPTION OF THE PREFERRED EMBODIMENTS

The present invention will be described in more detail with reference to various embodiments.

(First Embodiment)

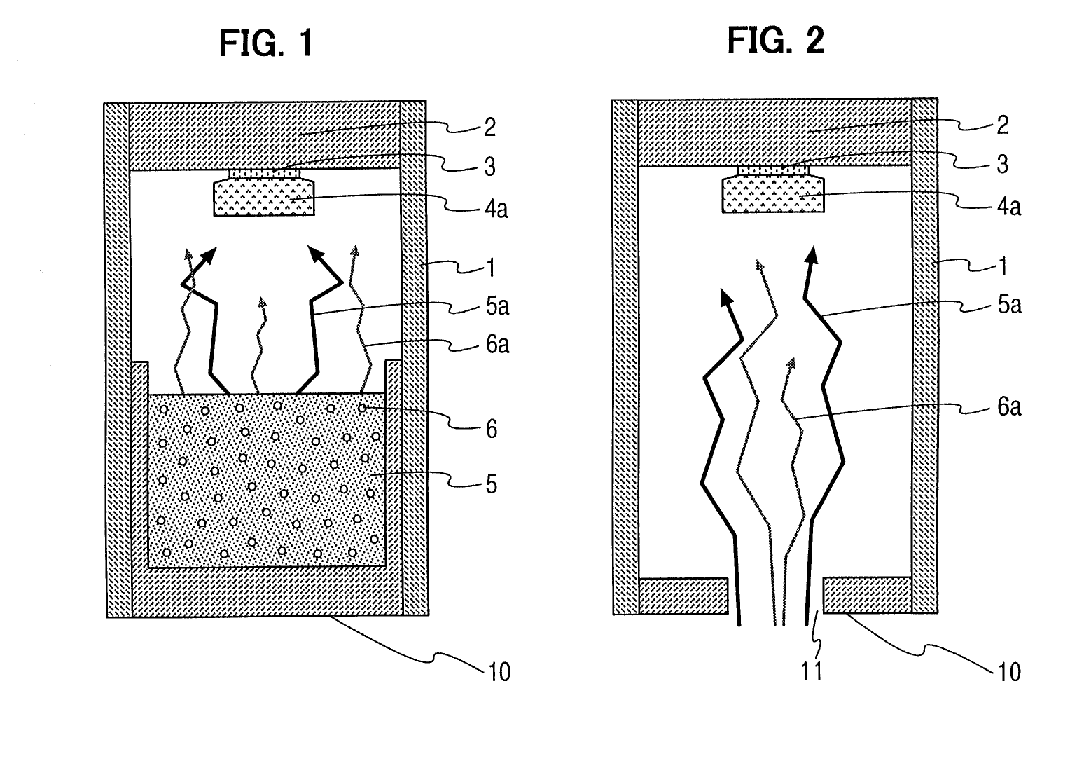

In the first embodiment shown in FIG. 1, an apparatus 10 for producing a crystal has a graphite vessel 1 and a graphite pedestal 2 that also functions as a cap for closing an upper opening of the graphite vessel 1. An SiC single crystal substrate 3 as a seed crystal is attached and fixed on a center of a lower surface of the graphite pedestal 2, and faces SiC raw material powder 5 charged in the lower half of the graphite vessel 1. The graphite vessel 1 has such a structure that a container having a bottom maintaining the SiC raw material powder 5 is installed in a cylindrical body having both open ends.

The apparatus 10 has a vacuum container (not shown) for containing the graphite vessel 1. The atmosphere and the pressure inside the graphite vessel 1 is controlled by connecting the vacuum container to a vacuum evacuation system and a gas supplying system The graphite vessel 1 is heated by a heating device (not shown) arranged on a periphery thereof. The temperature inside the graphite vessel 1 is controlled by adjusting the power input in the heating device.

In this embodiment, arsenic or an arsenic compound 6 is previously added and mixed with the SiC raw material powder 5 contained in the graphite vessel 1. When the SiC raw material powder 5 containing arsenic or an arsenic compound 6 is heated and sublimated, the SiC raw material gas 5 is mixed with a gas 6a containing arsenic or an arsenic compound, so as to grow an SiC single crystal 4a containing arsenic. As arsenic or an arsenic compound 6, for example, metallic arsenic is preferably used.

Arsenic is substituted on the Si site of SiC to function as an n-type dopant to decrease the resistivity of the resulting SiC single crystal 4a. Because arsenic has an atomic radius of 1.18 Å, which is equivalent to the atomic radius of silicon (1.17 Å), compression or expansion of the crystal does not occur by the addition of arsenic. Therefore, the SiC single crystal 4a having small crystalline distortion is obtained. The formation of heterogeneous polymorphism and the formation of defects due to the distortion are suppressed.

The arsenic concentration in the SiC single crystal 4a is preferably from 1×10¹⁶ to 1×10²⁰ cm⁻³, and can be appropriately selected within the range to make desired low resistivity. When the arsenic concentration is less than 1×10¹⁶ cm⁻³, no effect of decreasing the resistivity is obtained. When it exceeds 1×10²⁰ cm⁻³, there remains a possibility of adverse influence on the characteristics of SiC.

A process for producing an SiC single crystal using the apparatus 10 will be described.

An inert gas introduced into the vacuum container (not shown) is introduced into the interior of the graphite vessel 1 from gaps of from 1 to 10 mm of the graphite vessel 1, and the temperature of the SiC raw material powder 5 is heated by the heating device (not shown) to a temperature, in general, of from 2,000 to 2,500° C. At this time, a temperature gradient is provided inside the graphite vessel 1 by adjusting the heating device such that the temperature of the SiC single crystal substrate 3 is lower than the temperature of the SiC raw material powder 5. The pressure inside the graphite vessel 1 is then gradually decreased. Crystal growth by sublimation starts when the pressure reaches a value of from 0.1 to 100 Torr (from 13.3 Pa to 13.3 kPa).

Specifically, the SiC raw material powder 5 is sublimated to the raw material gas 5a containing gas species, such as Si, SiC₂ and Si₂C, and the raw material gas 5a is transported to the superjacent SiC single crystal substrate 3, and is recrystallized on the surface of the SiC single crystal substrate 3 having a relatively low temperature. Simultaneously,arsenic or arsenic compound 6 contained in the SiC raw material powder 5 is also sublimated or evaporated to the gas 6a containing arsenic or an arsenic compound. After the gas 6a containing arsenic or an arsenic compound is mixed with the raw material gas 5a, it is transported to the SiC single crystal substrate 3 along with the raw material gas 5a and is incorporated as an n-type dopant in the growing SiC single crystal 4a.

The SiC single crystal 4a thus grown contains arsenic having an atomic radius equivalent to silicon, and thus no distortion is formed inside the crystal. As a result, the heterogeneous polymorphism, such as 15R-type SiC, formed by the distortion inside the crystal upon growing 6H-type SiC, i.e., decrease of the distance between crystal planes, caused by the introduction of impurities can be suppressed. Therefore, an SiC single crystal of high quality having desired resistivity with few defects can be grown.

Experimental Result:

An experiment for growing an SiC single crystal was carried out by using the above apparatus and process of the first embodiment.

Metallic arsenic having a purity of 99% or more was mixed in SiC raw material powder 5 contained in the graphite vessel 1 in such an amount that provided an atomic ratio of about 10 ppm by weight with respect to SiC. A 6H-type crystal was used as the SiC single crystal 3, and the Si plane was used as a growing surface.

Heating was carried out under an inert gas atmosphere at 500 Torr (66.6 kPa) to make a temperature of the SiC raw material powder 5 of 2,300° C. and a temperature of the SiC single crystal substrate 3 of 2,200° C. Thereafter, the pressure was reduced, and when it reached about 100 Torr (13.3 kPa), growth of a single crystal for about 20 hours was carried out. As a result, a 6H-type SiC single crystal 4a of a growing amount of 8 mm was obtained.

The resulting SiC single crystal 4a was sliced to form a cross section, and the plane distance was obtained from an electron beam diffraction image by a TEM (transmission electron microscope). As a result, the plane distance in the <0001> direction was 2.52 Å, which was equivalent to the literature value (PROPERTIES OF SILICON CARBIDE, edited by Gery L. Harris, eims DATAREVIEW Ser. No. 13, pp. 4). The rate of change in volume per 1 mol of the crystal caused by the substitution of the impurity (i.e., arsenic) on the Si site or the C site of SiC was measured as the distortion in the crystal. The distortion in the crystal was 0.5% or less. Thus a crystal having high quality without distortion was obtained. The SiC single crystal 4a was of an n-type and had an arsenic concentration of 2.5×10¹⁸ cm⁻³ and resistivity of 120 mΩ·cm.

(Second Embodiment)

In the second embodiment shown in FIG. 2, in the apparatus 10 for producing a crystal, the SiC raw material powder 5 is not contained in the graphite vessel 1, but instead the SiC raw material gas 5a is supplied from a gas inlet 11 provided on the bottom surface of the graphite vessel 1. As the raw material gas 5a, for example, a mixed gas of silane (SiH₄) and propane (C₃H₈) may be used, as well as an SiC sublimated gas. The gas 6a containing arsenic or an arsenic compound is introduced along with the raw material gas 5a into the graphite vessel 1 having the similar temperature gradient as in the first embodiment. As the gas 6a containing arsenic or an arsenic compound, for example, arsine (ASH₃) can be preferably used.

In this embodiment, because the gas 6a containing arsenic or an arsenic compound is used, the addition and mixing thereof with the SiC raw material gas 5a can be easily carried out. Furthermore, the raw material gas 5a uniformly mixed reaches the SiC single crystal substrate 3, and arsenic is uniformly incorporated into the single crystal to provide a large effect of suppressing the formation of local crystalline distortion.

Therefore, an SiC single crystal of high quality having desired resistivity with few defects can be grown.

It is possible that the SiC raw material powder 5 as a supply source of the SiC raw material gas is contained in the graphite vessel 1, and only the gas 6a containing arsenic or an arsenic compound is introduced from the gas inlet. It is also possible that arsenic or an arsenic compound is contained in the constituent materials of the graphite vessel 1, and the SiC raw material powder 5 is contained therein, whereby the raw material gas 5a formed by sublimation by heating of the SiC raw material powder 5 is in contact and reacted with the inner surface of the graphite vessel 1 to incorporate arsenic into the raw material gas 5a. It is also possible that upon forming a coating layer of SiC on the inner surface of the graphite vessel 1, arsenic or an arsenic compound is incorporated in the coating layer. In any case, it is preferred that arsenic is uniformly contained in the graphite vessel 1 or the coating layer in order to obtain a uniform mixed gas.

Experimental Result:

An experiment for growing an SiC single crystal was carried out by using the above apparatus and process of the second embodiment.

Silane (SiH₄) and propane (C₃H₈) in a volume ratio of 3/1 as the raw material gas 5a were introduced into the graphite vessel 1, and arsine (ASH₃) as the gas 8a containing arsenic or an arsenic compound was mixed with the raw material gas 5a in an amount of about 5 ppm by volume. The gas amounts were adjusted to make an interior pressure of the graphite vessel 1 of about 200 Torr (26.6 kPa). A 6H-type crystal was used as the SiC single crystal 3, and the Si plane was used as a growing surface. Heating was carried out under an inert gas atmosphere at 500 Torr (66.6 kPa) to make a temperature of the SiC raw material powder 5 of 2,300° C. and a temperature of the SiC single crystal substrate 3 of 2,200° C. Thereafter, the pressure was reduced, and when it reached about 100 Torr (13.3 kPa), growth of a single crystal for about 20 hours was carried out. As a result, a 6H-type SiC single crystal 4a of a growing amount of 8 mm was obtained.

The resulting SiC single crystal 4a was sliced to form a cross section, and the plane distance was obtained from an electron beam diffraction image by a TEM (transmission electron microscope). As a result, the plane distance in the <0001> direction was 2.52 Å, which was equivalent to the literature value.

The distortion in the crystal was 1% or less, and thus a crystal having high quality without distortion was obtained. The SiC single crystal 4a was of an n-type and had an arsenic concentration of 3.0×10¹⁸ cm⁻³ and resistivity of 100 mΩ·cm.

(Third Embodiment)

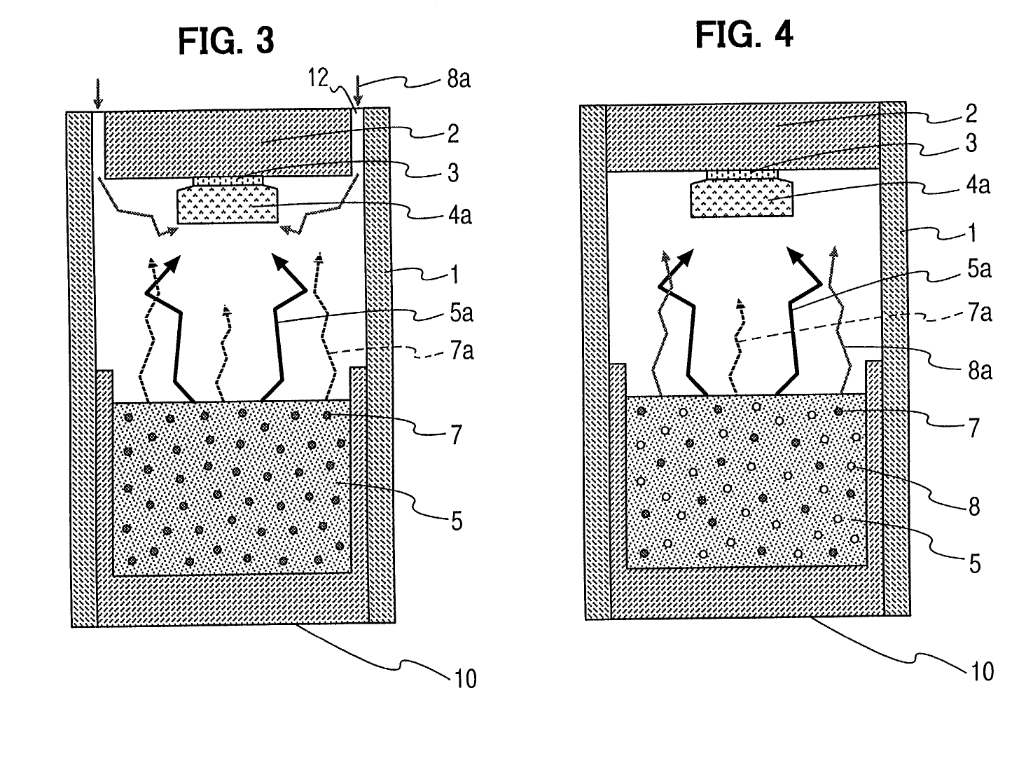

In the third embodiment shown in FIG. 3, an n-type dopant atom having a smaller atomic radius than silicon, or a compound thereof, and a metallic atom other than light metals having a larger atomic radius than silicon, or a compound thereof are incorporated into an SiC single crystal instead of arsenic or an arsenic compound.

In this embodiment, the SiC raw material powder 5 is contained in the graphite vessel 1, and a metallic atom (other than light metals) having a larger atomic radius than silicon, or a compound thereof is added to the SiC raw material powder 5. Light metals such as sodium, potassium, calcium and scandium have a density of less than 4 g/cm³, and have large differences in atomic radius from silicon to be a factor of crystal defects. Therefore, a metallic atom having an atomic radius smaller than them, specifically a metal having an atomic radius of from 1.17 to 1.60 Å or a metallic compound 7, is added thereto.

Examples of the metal or the metallic compound 7 include titanium (atomic radius: 1.46 Å), vanadium (atomic radius: 1.35 Å) and tantalum (atomic radius: 1.47 Å) for the metal, and a nitride and a carbide of these metals for the metallic compound. Titanium and vanadium are contained in the graphite vessel 1 and the SiC raw material powder 5 in a trace amount. Those are easily added thereto. Tantalum can be easily added in the form of an elemental substance or tantalum carbide.

After at least one of the metals and the metallic compounds is previously added to the SiC raw material powder 5, an inert gas is introduced into the interior of the graphite vessel 1, and it is heated to make a temperature of the SiC raw material powder 5 of from 2,000 to 2,500° C., whereby a gas containing the metal or the metallic compound 7a is mixed in the raw material gas 5a of the SiC raw material powder 5.

In addition, gas inlets 12 are provided in a periphery of the graphite pedestal 2. A gas containing the n-type dopant atom having a smaller atomic radius than silicon, or a compound thereof, specifically a gas containing nitrogen (atomic radius: 0.70 Å) or phosphorus (atomic radius: 1.10 Å) 8a, is introduced. The gas 8a containing nitrogen or phosphorus is mixed with the inert gas to introduce into the interior of the graphite vessel 1 when the interior of the graphite vessel 1 is heated and evacuated.

When the pressure inside the graphite vessel 1 is decreased to reach a value of from 0.1 to 100 Torr (from 13.3 Pa to 13.3 kPa), crystal growth by sublimation starts. Upon crystal growth by sublimation, the raw material gas 5a, which is formed by mixing the gas 7a containing nitrogen or phosphorus and the gas containing the metal or the metallic compound 7a with the raw material gas 5a formed with a sublimation gas of SiC, is transported to the SiC single crystal substrate 3 inside the graphite vessel 1, and nitrogen or phosphorus and the metal or the metallic compound are incorporated into the SiC single crystal 4a as an n-type dopant and a metallic impurity, respectively.

Nitrogen or phosphorus as an n-type dopant decreases the resistivity of the SiC single crystal 4a similar to arsenic in the foregoing embodiments. However, because nitrogen substituted on the C site of SiC has an atomic radius smaller than carbon (atomic radius: 0.77 Å), and phosphorus substituted on the Si site has an atomic radius smaller than silicon (atomic radius: 1.17 Å), they act on such a line that the crystal is compressed to provide crystalline distortion. On the other hand, because the metallic atom as an impurity has an atomic radius larger than silicon, it has such a function that expands the crystal. Consequently, when both the gas 8a containing nitrogen or phosphorus and the gas 7a containing the metal or the metallic compound are mixed in the raw material gas 5a, the compression action of the n-type dopant is counteracted, whereby an effect of relaxing distortion inside the crystal is obtained.

At this time, the concentration of nitrogen or phosphorus in the SiC single crystal 4a is preferably from 1×10¹⁶ to 1×10²⁰ cm⁻³, and both the desired low resistivity and the good crystallinity can be achieved within the range. When the concentration of nitrogen or phosphorus is less than 1×10¹⁶ cm⁻³, no effect of decreasing the resistivity is obtained. When it exceeds 1×10²⁰ cm⁻³₁ there remains a possibility of adverse influence on the characteristics of SiC. In order to relax the crystalline distortion caused by the n-type dopant, the concentration of the metallic impurity (such as titanium, vanadium and tantalum) in the SiC single crystal 4a is necessarily 1×10¹⁴ cm⁻³ or more. When the concentration of the metallic impurity is increased, the effect of decreasing the resistivity by the addition of the n-type dopant is counteracted. In order to avoid the counteraction, it is preferably 1×10¹⁸ cm⁻³ or less, and more preferably 1×10¹⁶ cm⁻³ or less. In general, it is preferred that it is set at a value smaller than the concentration of the n-type dopant by about from 1 to 2 digits or more, and a high effect can be obtained with a small addition amount.

As a result, an SiC single crystal 4a having small crystalline distortion can be obtained, and the heterogeneous polymorphism, such as 15R-type SiC, formed by the distortion inside the crystal upon growing 6H-type SiC, i.e., decrease of the distance between crystal planes, can be suppressed. Therefore, the similar effect as in the foregoing embodiments can be obtained, that is, an SiC single crystal of high quality having desired resistivity with few defects can be grown.

Experimental Result:

An experiment for growing an SiC single crystal was carried out by using the above apparatus and process of the third embodiment.

Metallic titanium (Ti) having a purity of 99% or more as the metal or the metallic compound 7 was mixed in SiC raw material powder 5 contained in the graphite vessel 1 in such an amount that provided an atomic ratio of about 5 ppm by weight with respect to Sic. A 6H-type crystal was used as the Sic single crystal 3, and the Si plane was used as a growing surface. Heating was carried out under an inert gas atmosphere at 500 Torr (66.6 kPa) to make a temperature of the SiC raw material powder 5 of 2,300° C. and a temperature of the SiC single crystal substrate 3 of 2,200° C. Thereafter, the pressure was reduced. When it reached about 100 Torr (13.3 kPa), nitrogen as the gas 8a containing nitrogen or phosphorus was mixed with the inert gas in an amount of about 0.1% volume. Thereafter, growth of a single crystal for about 20 hours was carried out. As a result, a 6H-type SiC single crystal 4a of a growing amount of 8 mm was obtained.

The resulting SiC single crystal 4a was sliced to form a cross section, and the plane distance was obtained from an electron beam diffraction image by a TEM (transmission electron microscope). As a result, the plane distance in the <0001> direction was 2.51 Å, which was equivalent to the literature value, the distortion in the crystal was 1% or less and thus a crystal having high quality without distortion was obtained. The SiC single crystal 4a was of an n-type and had a nitrogen concentration of 6.0×10¹⁸ cm⁻³, a titanium concentration of 5.0×10¹⁵ cm⁻³, and resistivity of 60 mΩ·cm.

The similar results were obtained in the cases where titanium nitride (TiN), vanadium (V), vanadium nitride (VN), vanadium carbide (VC), tantalum (Ta), tantalum carbide (TaC) and tantalum nitride (TaN) were mixed in an amount of about from 0.5 to 5 ppm by weight instead of metallic titanium (Ti), and in the cases where phosphorus (P₂ or P₄) was mixed in an amount of about from 0.05 to 0.1% by volume instead of nitrogen as the gas 8a containing nitrogen or phosphorus.

(Fourth Embodiment)

In the fourth embodiment shown in FIG. 4, the gas containing nitrogen or phosphorus as an n-type dopant is not introduced from the outside, but instead a nitrogen compound or a phosphorus compound 8 is added and mixed with the SiC raw material powder 5 contained in the graphite vessel 1, along with a metal having an atomic radius of from 1.17 to 1.60 Å or a metallic compound 7.

In this embodiment, upon heat sublimation of the SiC raw material powder 5, the gas 7a containing the metal or the metallic compound and the gas 8a containing nitrogen or phosphorus are mixed with the raw material gas 5a, and the mixed gas is transported to the SiC single crystal substrate 3. Therefore, similar to the third embodiment, the compression action of nitrogen or phosphorus which is an n-type dopant is counteracted by the metallic impurity to obtain an SiC single crystal 4a having small crystalline distortion. Thus, an SiC single crystal of high quality having desired resistivity with few defects can be grown.

Experimental Result:

An experiment for growing an SiC single crystal was carried out by using the above apparatus and process of the fourth embodiment.

Metallic phosphorus (P) having a purity of 99% or more as the compound of nitrogen or phosphorus 8 was mixed in SiC raw material powder 5 contained in the graphite vessel 1 in such an amount that provided an atomic ratio of about 50 ppm by weight with respect to SiC. Furthermore, metallic titanium (Ti) having a purity of 99% or more as the metal or the metallic compound 7 was mixed therein in such an amount that provided an atomic ratio of about 5 ppm by weight with respect to SiC. A 6H-type crystal was used as the SiC single crystal 3, and the Si plane was used as a growing surface. Heating was carried out under an inert gas atmosphere at 500 Torr (66.6 kPa) to make a temperature of the SiC raw material powder 5 of 2,300° C. and a temperature of the SiC single crystal substrate 3 of 2,200° C. Thereafter, the pressure was reduced. When it reached about 100 Torr (13.3 kPa), growth of a single crystal for about 20 hours was carried out. As a result, a 6H-type SiC single crystal 4a of a growing amount of 8 mm was obtained.

The resulting SiC single crystal 4a was sliced to form a cross section, and the plane distance was obtained from an electron beam diffraction image by a TEM (transmission electron microscope). As a result, the plane distance in the <0001> direction was 2.51 Å, which was equivalent to the literature value. The distortion in the crystal was 1% or less, and thus a crystal having high quality without distortion was obtained. The SiC single crystal 4a was of an n-type and had a phosphorus concentration of 2.5×10¹⁸ cm⁻³, a titanium concentration of 5.0×10¹⁵ cm⁻³, and resistivity of 120 mΩ·cm.

(Fifth Embodiment)

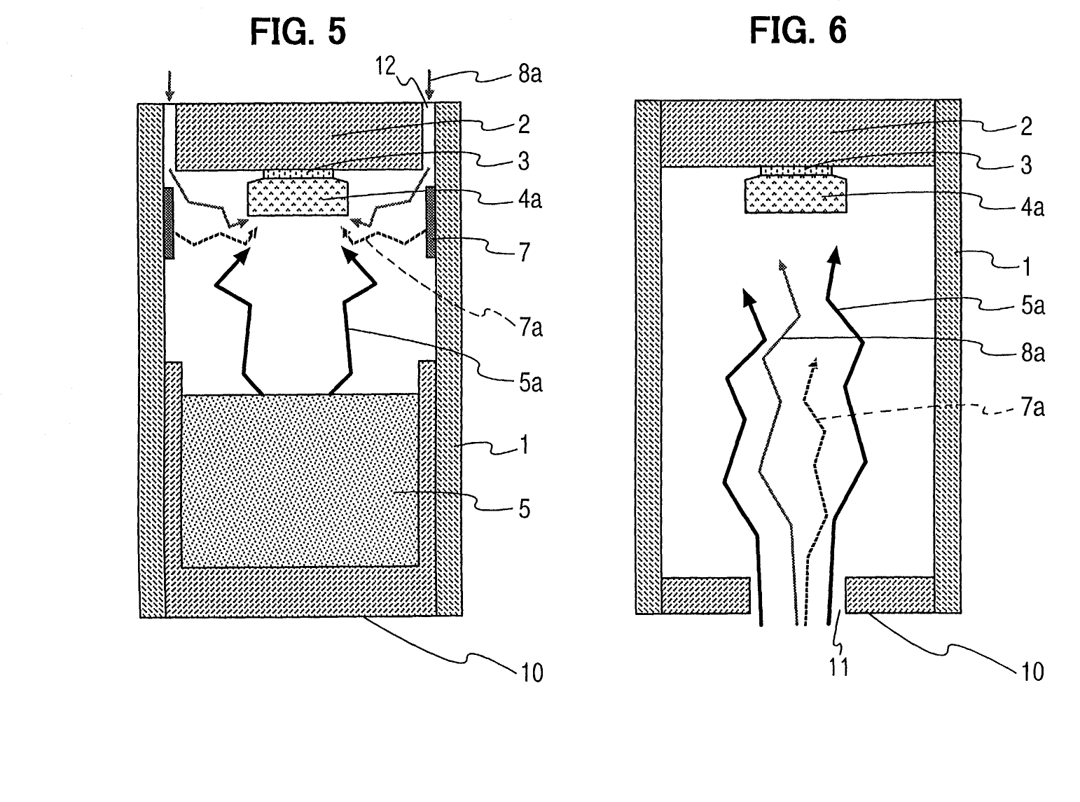

In the fifth embodiment shown in FIG. 5, a metal or a metallic compound 7 having an atomic radius of from 1.17 to 1.60 Å is not added to the SiC raw material powder 5 contained in the graphite vessel 1, but instead it is formed into a cylindrical form and fixed on the inner surface of the graphite vessel 1 beneath the SiC single crystal substrate 3. The gas 8a containing nitrogen or phosphorus which is an n-type dopant is introduced from the outside through the gas inlets 12.

In this embodiment, upon heat sublimation of the SiC raw material powder 5, the gas 7a containing the metal or the metallic compound and the gas 8a containing nitrogen or phosphorus are mixed with the raw material gas 5a, and the mixed gas is transported to the SiC single crystal substrate 3. Therefore, similar to the third embodiment, the compression action of nitrogen or phosphorus which is an n-type dopant is counteracted by the metallic impurity to obtain an SiC single crystal 4a having small crystalline distortion. Thus, an SiC single crystal of high quality having desired resistivity with few defects can be grown.

(Sixth Embodiment)

In the sixth embodiment shown in FIG. 6, the SiC raw material powder 5 is not contained in the graphite vessel 1, but instead the raw material gas 5a is supplied from the gas inlet 11 provided on the bottom of the graphite vessel 1. The gas 7a containing the metal having an atomic radius of from 1.17 to 1.60 Å or the metallic compound and the gas 8a containing nitrogen or phosphorus are introduced along with the raw material gas 5a.

In this embodiment, the gas 7a containing the metal or the metallic compound and the gas 8a containing nitrogen or phosphorus can be easily mixed with the raw material gas 5a, and the uniform mixed gas can be transported to the SiC single crystal substrate 3. Therefore, similar to the third embodiment, the compression action of nitrogen or phosphorus which is an n-type dopant is counteracted by the metallic impurity to obtain an SiC single crystal 4a having small crystalline distortion. Thus, an SiC single crystal of high quality having desired resistivity with few defects can be grown.

Experimental Result:

An experiment for growing an SiC single crystal was carried out by using the above apparatus and process of the sixth embodiment. Silane (SiH₄) and propane (C₃H₈) in a volume ratio of 3/1 as the raw material gas 5a were introduced into the graphite vessel 1, and the nitrogen gas 7a as the n-type dopant atom was mixed with the raw material gas 5a in an amount of about 50 ppm by volume. Furthermore, metallic vanadium (V) having a purity of 99% or more as the metal or the metallic compound 7a was gasified and mixed with the raw material gas 5a in an amount of about 2 ppm by volume. The gas amounts were adjusted to make an interior pressure of the graphite vessel 1 of about 200 Torr (26.6 kPa). A 6H-type crystal was used as the SiC single crystal 3, and the Si plane was used as a growing surface. Heating was carried out under an inert gas atmosphere to make a temperature of the SiC single crystal substrate 3 of 2,200° C. Growth of a single crystal for about 6 hours was carried out. As a result, a 6H-type SiC single crystal 4a of a growing amount of 3 mm was obtained.

The resulting SiC single crystal 4a was sliced to form a cross section, and the plane distance was obtained from an electron beam diffraction image by a TEM (transmission electron microscope). As a result, the plane distance in the <0001> direction was 2.51 Å, which was equivalent to the literature value.

The distortion in the crystal was 1% or less, and thus a crystal having high quality without distortion was obtained. The SiC single crystal 4a was of an n-type and had a nitrogen concentration of 3.0×10¹⁸ cm⁻³ and a vanadium concentration of 2.0×10¹⁵ cm⁻³.

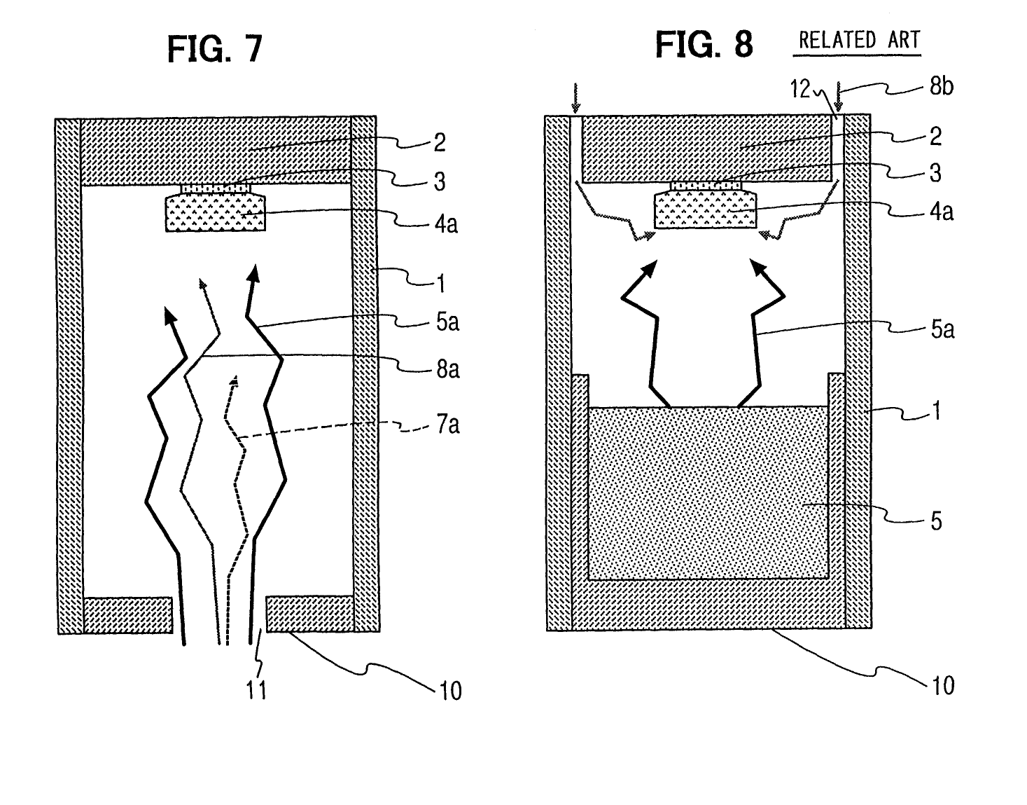

(Seventh Embodiment) In the seventh embodiment shown in FIG. 7, carbon fluoride gas is introduced as the gas 7a along with the raw material gas 5a, in place of the metal or the metallic compound used in the sixth embodiment. Further, gas including at least one of boron, aluminum and gallium is used as the gas 8a, in place of the nitrogen or phosphorus used in the sixth embodiment.

Experimental Result:

An experiment for growing an SiC single crystal was carried out by using the above apparatus and process of the seventh embodiment.

Silane (SiH₄) and propane (C₃H₈) in a volume ratio of 3/1 as the raw material gas 5a were introduced into the graphite vessel 1, and an alkyl aluminum (((CH₃)₃Al)₂) as the gas 8a containing boron, aluminum or gallium as a p-type dopant was gasified and mixed with the raw material gas 5a in an amount of about 50 ppm by volume.

Furthermore, a carbon fluoride gas (CF₄) 7a as an atom having an atomic radius smaller than silicon, or a compound thereof was mixed with the raw material gas 5a in an amount of about 5 ppm by volume. The gas amounts were adjusted to make an interior pressure of the graphite vessel 1 of about 200 Torr (26.6 kPa). A 6H-type crystal was used as the SiC single crystal 3, and the Si plane was used as a growing surface. Heating was carried out under an inert gas atmosphere to make a temperature of the SiC single crystal substrate 3 of 2,200° C. Growth of a single crystal for about 6 hours was carried out. As a result, a 6H-type SiC single crystal 4a of a growing amount of 2.5 mm was obtained.

The resulting SiC single crystal 4a was sliced to form a cross section, and the plane distance was obtained from an electron beam diffraction image by a TEM (transmission electron microscope). As a result, the plane distance in the <0001> direction was 2.54 Å, which was equivalent to the literature value.

The distortion in the crystal was 1% or less, and thus a crystal having high quality without distortion was obtained. The SiC single crystal 4a was of a p-type and had an aluminum concentration of 3.0×10¹⁸ cm⁻³ and a fluorine concentration of 2.0×10^{15 cm}⁻³.

Comparison Result:

For comparison, an experiment for growing an SiC single crystal was carried out by using the apparatus 10 and process shown in FIG. 8.

SiC having a purity of 99% of more was used as the SiC raw material powder 5 contained in the graphite vessel 1. 6H-type crystal was used as the SiC single crystal 3, and the Si plane was used as a growing surface. Heating was carried out under an inert gas atmosphere at 500 Torr (66.6 kPa) to make a temperature of the SiC raw material powder 5 of 2,300° C. and a temperature of the SiC single crystal substrate 3 of 2,200° C. Thereafter, the pressure was reduced. When it reached about 100 Torr (13.3 kPa), nitrogen as the gas 8b containing nitrogen was mixed with the inert gas in an amount of about 0.1% volume. Thereafter, growth of a single crystal for about 20 hours was carried out. As a result, an SiC single crystal of a 6H-type and a 15R-type as a mixture of a growing amount of 8 mm was obtained.

The resulting SiC single crystal was sliced to form a cross section, and the plane distance was obtained from an electron beam diffraction image by a TEM (transmission electron microscope). As a result, the plane distance in the <0001> direction was 2.48 Å, which was smaller than the literature value. The distortion in the crystal was 1.5% or more. Thus it was found that a 15R-type crystal was formed due to the occurrence of distortion. The SiC single crystal was of an n-type and had a nitrogen concentration of 6.0×10¹⁸ cm⁻³ and resistivity of 60 mΩ·cm.

The present invention should not be limited to the disclosed embodiments, but may be implemented in other ways without departing from the spirit of the invention.

What is claimed is:

1. A process for producing a silicon carbide single crystal comprising steps of:
placing a silicon carbide single crystal substrate as a seed crystal in a vessel; and
supplying, on the silicon carbide single crystal substrate, a silicon carbide raw material gas including at least one of arsenic and arsenic compound therein.

2. A process for producing a silicon carbide single crystal as in claim 1, wherein:
silicon carbide raw material powder as a supply source of the silicon carbide raw material gas is arranged in the vessel; and
the at least one of arsenic and arsenic compound is added to the silicon carbide raw material powder.

3. A process for producing a silicon carbide single crystal as in claim 1, wherein:
the at least one of arsenic and arsenic compound is provided in the vessel.

4. A process for producing a silicon carbide single crystal as in claim 1, wherein:
a gas containing the at least one of arsenic and arsenic compound is introduced into an interior of the vessel.

5. A process for producing a silicon carbide single crystal comprising:
placing a silicon carbide single crystal substrate as a seed crystal in a vessel; and
supplying, on the silicon carbide single crystal substrate, a silicon carbide raw material gas including at least one of an n-type dopant atom having a smaller atomic radius than silicon and a compound thereof, and at least one of a metallic atom other than light metals having a larger atomic radius than silicon and a compound thereof.

6. A process for producing a silicon carbide single crystal as in claim 5, wherein:
an addition amount of the metallic atom is such an amount that is smaller than an addition amount of the n-type dopant atom but is larger than an amount required for relaxing crystalline distortion caused by the n-type dopant atom.

7. A process for producing a silicon carbide single crystal as in claim 5, wherein:
the n-type dopant atom is at least one selected from nitrogen and phosphorus.

8. A process for producing a silicon carbide single crystal as in claim 5, wherein:
the metallic atom is an atom having an atomic radius of from 1.17 to 1.60 Å.

9. A process for producing a silicon carbide single crystal as in claim 8, wherein:
the metallic atom is at least one selected from titanium, vanadium and tantalum.

10. A process for producing a silicon carbide single crystal as in claim 5, wherein:
,the at least one of n-type dopant atom and compound thereof is added to the silicon carbide raw material gas by supplying a gas containing the at least one of n-type dopant atom and compound thereof to an interior of the vessel.

11. A process for producing a silicon carbide single crystal as claimed in claim 5, wherein:
the silicon carbide raw material powder as a supply source of the silicon carbide raw material gas are arranged in the vessel; and
the at least one of metallic atom and compound thereof is added to the silicon carbide raw material gas by adding the metallic atom and compound thereof to the silicon carbide raw material powder.

12. A process for producing a silicon carbide single crystal as in claim 5, wherein:
the at least one of the metallic atom and compound thereof is provided in the vessel.

13. A process for producing a silicon carbide single crystal as in claim 5, wherein:
a gas containing at least one of the metallic atom and compound thereof is supplied into an interior of the vessel.

14. A silicon carbide single crystal comprising:
a crystalline structure containing arsenic therein.

15. A silicon carbide single crystal as in claim 14, wherein:
concentration of the arsenic is from 1×10¹⁶ to 1×10²⁰ cm⁻³.

16. A silicon carbide single crystal comprising:
a crystalline structure containing an n-type dopant atom having a smaller atomic radius than silicon and a metallic atom other than light metals having a larger atomic radius than silicon in a crystalline structure thereof.

17. A silicon carbide single crystal as in claim 16, wherein:
concentration of the n-type dopant atom is from 1×10¹⁶ to 1×10²⁰ cm⁻³.

18. A silicon carbide single crystal as in claim 16, wherein:
concentration of the metallic atom is from 1×10¹⁴ to 1×10¹⁸ cm⁻³.

19. A process for producing a silicon carbide single crystal comprising steps of:
placing a silicon carbide single crystal substrate as a seed crystal in a vessel; and
supplying, on the silicon carbide single crystal substrate, a silicon carbide raw material gas including at least one of a p-type dopant atom having a larger atomic radius than carbon and compound thereof, and at least one of an atom having a smaller atomic radius than silicon and compound thereof.

20. A process for producing a silicon carbide single crystal as in claim 19, wherein:
an addition amount of the atom having a smaller atomic radius than silicon is such an amount that is smaller than an addition amount of the p-type dopant atom but is larger than an amount required for relaxing crystalline distortion caused by the p-type dopant atom.

21. A process for producing a silicon carbide single crystal as in claim 19, wherein:
the p-type dopant atom is at least one selected from boron, aluminum and gallium.

22. A process for producing a silicon carbide single crystal as in claim 19, wherein:
the atom having a smaller atomic radius than silicon is an atom having an atomic radius of from 0.64 to 1.17 Å.

23. A process for producing a silicon carbide single crystal as in claim 22, wherein:
the atom having a smaller atomic radius than silicon is a carbon fluoride gas.

24. A process for producing a silicon carbide single crystal as in claim 19, wherein:
a gas containing at least one of the p-type dopant atom and compound thereof is supplied to an interior of the vessel.

25. A process for producing a silicon carbide single crystal as in claim 19, wherein:
silicon carbide raw material powder as a supply source of the silicon carbide raw material gas is arranged in the vessel; and
the at least one of the atom having a smaller atomic radius than silicon and compound thereof is added to the silicon carbide raw material gas.

26. A process for producing a silicon carbide single crystal as in claim 19, wherein:
the at least one of the atom having a smaller atomic radius than silicon and compound thereof is provided in at least an inner surface of the vessel.

27. A process for producing a silicon carbide single crystal as in claim 19, wherein:
the at least one of the atom having a smaller atomic radius than silicon and compound thereof is supplied as a gas into the vessel.

28. A silicon carbide single crystal comprising:
a crystalline structure including a p-type dopant atom having a larger atomic radius than carbon and an atom having a smaller atomic radius than silicon.

29. A silicon carbide single crystal as in claim 28, wherein:
concentration of the p-type dopant atom is from 1×10¹⁶ to 1×10²⁰ cm⁻³.

30. A silicon carbide single crystal as in claim 28, wherein:
concentration of the atom having a smaller atomic radius than silicon of from 1×10¹⁴ to 1×10¹⁸ cm⁻³.
